(19) United States
(12) Patent Application Publication
(10) Pub. No.: US 2008/0151512 A1
(43) Pub. Date: Jun. 26, 2008

(54) Enhanced Ball Grid Array Package

(76) Inventor: Kenneth W. Johnson, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/615,484

(22) Filed: Dec. 22, 2006

(51) Int. Cl. H05K 5/02

(52) U.S. Cl. 361/759

(57) ABSTRACT

An integrated circuit substrate has an array of surface interconnects and corner features with attachment elements. The corner features extend past the generally rectilinear perimeter of the substrate providing a lever arm to enhance the strength of the attachment elements thereby protecting the integrity of the array of surface interconnects.

### BACKGROUND

Ball grid array (herein “BGA”) packages are known and commonly used in many electronic applications. During manufacture and test of printed circuit boards (herein “PCB”), failures stemming from the presence of the BGA are known to occur. It has been identified that failures are commonly due to shock, vibration and thermal stresses causing flexure of the PCB relative to the BGA package and, thereby, separation of one or more of the balls in the grid from the PCB. It has further been identified that failures from ball separation are most common at the corners of the BGA package and with thick BGA package styles. This is consistent with the identified failure mode because it is known that thick BGA packages are stiffer than thin BGA packages and do not flex as well with flexure of the PCB.

U.S. patent application Ser. No. 11/405337 filed Apr. 27, 2006 and entitled “Improved Ball Grid Array Package”, which is commonly owned and assigned, is hereby incorporated by reference, and teaches the use of sacrificial balls in the array to render certain ball separation failures benevolent. In many cases, the sacrificial balls solve the failure issue, but in some cases, the sacrificial balls in the array create difficulty in signal routing for the rest of the balls in the array.

There is a need, therefore, for an improved BGA package that addresses the ball separation failures without rendering signal routing more difficult.

### BRIEF DESCRIPTION OF THE DRAWINGS

An understanding of the present teachings can be gained from the following detailed description, taken in conjunction with the accompanying drawings of which like reference numerals in different drawings refer to the same or similar elements.

FIG. 1 is a perspective view of a IC package according to the present teachings that includes an example of each one of three embodiments according to the present teachings.

### DETAILED DESCRIPTION

In the following detailed description, for purposes of explanation and not limitation, example embodiments disclosing specific details are set forth in order to provide an understanding of embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatus and methods may be omitted so as to not obscure the description of the example embodiments. Such methods and apparatus are clearly within the scope of the present teachings.

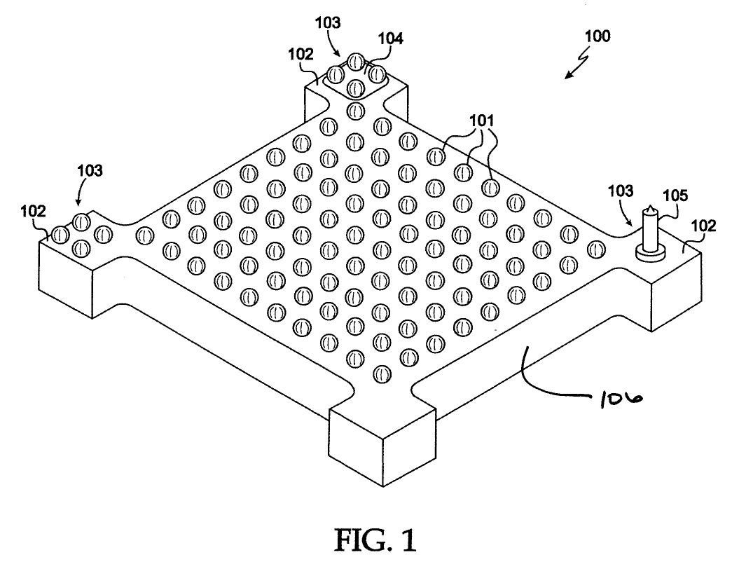

With specific reference to FIG. 1 of the drawings, there is shown a perspective view of a BGA package 100 according to the present teachings which is constructed from a “thick” BGA substrate 106, typically greater than 1 mm, as is generally known in the semiconductor arts. The substrate 106 of the BGA package 100 that carries surface interconnects 101 of the array is generally rectilinear or square in shape. In a specific embodiment, the surface interconnects 101 are generally hemi-spherical and are termed “balls” of the ball grid array to those of ordinary skill in the art. The surface interconnects 101 may also be cylindrical or hemi-ellipsoidal and still benefit from a package design according to the present teachings.

At each corner of the substrate 106 is a corner feature 102. In a specific embodiment, the corner feature 102 is an extension of the BGA package corners in another generally rectilinear shape. Each corner feature 102 extends past the generally rectilinear perimeter of the portion of the BGA package 100 that carries the surface interconnects 102 of the array. Each corner feature 102 includes an attachment element 103. Advantageously, the extension of the corner feature 102 in combination with the attachment element 103 provides a lever arm that accepts most of the stress placed on the array of the package to decrease stress placed on corners of the array of the BGA package 100.

Multiple embodiments of the attachment element 103 are all shown on FIG. 1 for simplicity. One of ordinary skill in the art appreciates, however, that in a practical application, the attachment elements 103 at each corner feature 102 are typically identical embodiments.

A first embodiment of the attachment element 103 according to the present teachings is one or more surface interconnects 101. Advantageously, the attachment element 103 comprising surface interconnects 101 on each corner feature 102 provide additional attachment strength for the package 100 and are straightforward to implement in the IC package manufacturing process because they are consistent with surface interconnects already part of the manufacturing process. The greater the size and number of surface interconnects 101 on each corner feature 102, the more additional strength the corner features 102 add to the overall package 100.

A second embodiment of the attachment element 103 according to the present teachings is similar to the first embodiment with the addition of a planar feature 104 disposed between the corner feature 102 and the one or more surface interconnects 101. In a specific embodiment, the planar feature 104 is made of metal, but because it is not necessary that the planar feature 104 be conductive, other materials are also appropriate. Advantageously, the planar feature 104 provides additional surface area of attachment to the corner feature 102 for increased attachment strength. The planar feature 104 is a larger pad similar to pads that are conventionally used with the surface interconnects 101 of the array. The planar feature 104 according to the present teachings is larger and is attached to one or more surface interconnects on the corner feature 102. Advantageously, the planar feature 104 is larger providing greater adhesion strength to the substrate 106.

A third embodiment of the attachment element 103 according to the present teachings is a pin interconnect 105. The pin interconnect 105 uses a conventional through pin attachment to the PCB. Specifically, the through pin interconnect 105 is received by an annular metalized via in the PCB to which the BGA attaches providing for the most additional strength of the three embodiments. Advantageously, the attachment element 103 comprising the pin interconnect 105 on each corner feature 102 provides the best attachment strength for the package 100 and is straightforward to implement in the IC package manufacturing process because it is conventional, but requires additional steps.

Embodiments of the teachings are described herein by way of example with reference to the accompanying drawings describing an enhanced BGA package that resists a known failure mode while also permitting uninhibited routing options for signals of the array. Other variations, adaptations, and embodiments of the present teachings will occur to those of ordinary skill in the art given benefit of the present teachings, such as different styles of attachment elements 103, and are considered within the scope of the appended claims.

1. An apparatus comprising:
a substrate being generally planar, with first and second major surfaces, the first and second major surfaces having a rectilinear perimeter and an array of surface interconnects disposed on the first major surface, the substrate having corner features at each corner of the rectilinear perimeter that extend past the rectilinear perimeter of the substrate wherein each corner feature comprises attachment elements.

2. An apparatus as recited in claim 1 wherein each attachment element is at least one surface interconnect.

3. An apparatus as recited in claim 1 wherein each attachment element is a pin interconnect.

4. An apparatus as recited in claim 1 wherein the attachment elements are substantially hemi-spherical surface interconnects.

5. An apparatus as recited in claim 4 and further comprising a planar feature disposed between the corner feature and the attachment elements.

6. An apparatus as recited in claim 1 wherein the attachment elements are substantially cylindrical surface interconnects.

7. An apparatus as recited in claim 1 and further comprising a printed circuit board (“PCB”) on which the rectilinear substrate is attached.
